(19) United States
(12) Patent Application Publication
(10) Pub. No.: US 2016/0157355 A1
(43) Pub. Date: Jun. 2, 2016

(54) Design Support System, Design Support Method and Design Support Program

(71) Applicant: HITACHI, LTD., Chiyoda-ku, Tokyo (JP)

(72) Inventors: Umberto PAOLETTI, Tokyo (JP); Yasumaro KOMIYA, Tokyo (JP)

(21) Appl. No.: 14/905,358

(22) PCT Filed: Aug. 1, 2013
(86) PCT No.: PCT/JP2013/071577

§ 371 Date: Jan. 15, 2016

(51) Int. Cl. H05K 3/00; G06F 17/50

(52) U.S. Cl. CPC H05K 3/0005; G06F 17/5072

(57) ABSTRACT

A design support system for designing a printed circuit board, comprising: a database for storing layout data, noise source data of the printed circuit board, and calculation results; a data reading unit for reading noise source data and local layout data of a local area around the noise source from the database; a bypass devices introducing unit for introducing current bypass devices to the local area, and a calculation unit for estimating the radiation effective forward wave power injected into assumed infinite power supply planes of the printed circuit board from the noise source without and with current bypass devices, and for calculating their ratio.

### FIELD OF THE INVENTION

This invention relates to systems and methods to support design of electrical equipment, in particular to support the design of printed circuit boards with low electromagnetic emissions.

### BACKGROUND OF THE INVENTION

Power supply noise of printed circuit boards (PCBs) is a source of high frequency electromagnetic interferences (EMI), and it is mainly generated by simultaneous switching of large scale of integration (LSI) integrated circuits (ICs) (LSI-ICs in short LSIs). FIG. 3 is a longitudinal section view of an example of a PCB 20 with two planes (a power plane 23 and a ground plane 24 in dielectric 22), LSI 21, via 25, and bypass capacitors 26. The simultaneous switching noise (SSN) propagates as an electromagnetic (EM) noise wave 27 between the power supply planes (23, 24) and most of it is reflected back as reflected wave 29 by the board edges (28), creating resonances that are dependent on the board layout as shown in FIG. 3.

In order to reduce the power supply noise, bypass capacitors are often used. In multi-layer PCBs having at least two ground planes, ground vias can be a more effective way to reduce the radiation. Sometimes open stubs in stripline or microstrip technology are used as well. In the present invention, devices that act as bypass for the current between power and ground planes, or between ground planes, like the above ones, but not only the above ones, are called current bypass devices.

The state of the art for estimating the radiation consists in evaluating the voltage along the edges of the power supply planes, in replacing the edge voltage with an equivalent magnetic current, and in calculating the radiated field from this equivalent magnetic current. One problem of this method is that simulations of the whole PCB planes are required, including all the components connected to the planes. Although very important progresses have been made recently in PCB simulation techniques, this still requires considerable calculation time, and must be repeated when the layout is changed during the design phase. A second problem is that models of LSIs and other components are not always available, compromising the accuracy of the calculation.

A few patents related to system and methods to estimate the radiation from electronic equipment exist, e.g. the U.S. Pat. No. 6,598,208 B2.

Several non-patent documents related to techniques to estimate the radiation from edges of PCBs using equivalent magnetic current, for example Non Patent Document 1 and Non Patent Document 2. The method requires knowledge of the whole plane layout and of all the components connected to the planes, because the radiation is affected by the board resonances.

Non Patent Document 1: M. Leone: “The radiation of a rectangular power-bus structure at multiple cavity-mode resonances,” IEEE Transactions on Electromagnetic Compatibility, vol. 45, no. 3, pp. 486-492, August 2003.

Non Patent Document 2: X. Duan, R. Rimolo-Donadio, H.-D. Bruns, and C. Schuster: “A Combined Method for Fast Analysis of Signal Propagation, Ground Noise, and Radiated Emission of Multilayer Printed Circuit Boards,” IEEE Transactions on Electromagnetic Compatibility, vol. 52, no. 2, pp. 487-495, May 2010.

Several patents cover methods to assist the placement of current bypass devices, in particular bypass (sometimes called decoupling) capacitors, e.g. the U.S. Pat. Nos. 6,571,184 B2, 6,598,208 B2, 6,789,241 B2 and 6,850,878 B2.

The U.S. Pat. No. 7,149,666 B2 covers methods for modeling interactions between vias in multi-layered packaging using simulations with an infinite board.

Non Patent Document 3 covers possible methods to calculate a via port current and makes use of the analysis technique for multilayer PCBs, including a definition of the via ports for multilayer PCBs. Of particular interest here is the method consisting in calculating the multiport models of pairs of planes at the via ports, and in combining them along the vertical direction to obtain the multi-layer board model. In the Non Patent Document 3, this techniques is applied to both finite and infinite boards using the well known cylindrical wave expansion between each plane pair.

Non Patent Document 3: Er-Ping Li: “Electrical Modeling and Design for 3D System Integration,” Wiley, pp. 281-296 and 305-316, 2012.

### SUMMARY OF THE INVENTION

The method described in US patent document 6,598,208 B2 focuses on different radiation mechanisms and not on the radiation from the PCB edges.

The methods described in Non Patent Documents 1 and 2 for calculating the radiation consider the effect of the edges because only finite boards are used.

Methods described in U.S. Pat. No. 6,571,184 B2, 6,598,208 B2, 6,789,241 B2 and 6,850,878 B2 focus on power integrity (PI) or signal integrity (SI), and not on the radiation from the PCB edges. Furthermore, the patents calculate the self and transfer impedances including board resonances, and therefore require information about the whole plane layout and about all the components connected to the planes.

The methods described in U.S. Pat. No. 7,149,666 B2 covers methods for modeling interactions between vias in multi-layered packaging using simulations with an infinite board. However, the method described in the U.S. Pat. No. 7,149,666 is PI and SI oriented.

The methods described in Non Patent Document 3 include also the case for an infinite board, but not for calculating the radiation from the PCB edges. The method described in the Non Patent Document 3 may be applied to calculate the radiation from a finite size board similarly to Non Patent Documents 1 and 2, but since the whole PCB must be considered, a remarkable calculation time is required.

It would therefore be desirable to provide a system and method for support the design of electrical equipment with low electromagnetic emissions, by simplified calculation.

One aspect of the present invention is that all the calculations and estimations are made using a model of the electrical equipment and an infinite planes assumption, that is without considering the reflected waves from the edges of the electrical equipment.

Another aspect is that only vias and devices that are very close to a noise source device (LSI) in a local area of the model. The maximum distance is in the order of the LSI dimensions (few tens of millimeters typically).

Another aspect is that the radiation calculation method makes use of a new concept that is called ‘equivalent radiation effective forward wave’ or more simply ‘radiation effective forward wave’, which corresponds to the equivalent wave obtained by algebraically adding up voltages and currents of the single waves propagating among assumed infinite power supply planes.

Another aspect is that the effect of current bypass devices on the radiation is approximately estimated based on the ratio of the power of the radiation effective wave injected into infinite planes without and with the current bypass devices.

Another aspect is that the selection of the position and values of current bypass devices can be automatized. When it is made by the user it is facilitated by plots of the horizontal distribution of the voltage between the bottom and top planes. Given the PCB layout close to a noise source device (LSI), the present invention helps the user to select a suitable configuration of current bypass devices for reducing the electromagnetic radiation from the PCB edges.

The most advantageous effect of the present invention is that the design of electrical equipment, such as PCBs, with lower electromagnetic radiation from the edges is greatly simplified.

One advantage of the present approach is that only local simulations in the local region around the noise source device are required, reducing in this way the calculation time and the need for information about the layout and most of the components. The reduction of calculation time can be also translated into the possibility of using optimization algorithms to automatically select configurations of current bypass devices.

Another favorable consequence of the locality of the simulations is that the procedure can be applied before the whole design has been completed, further reducing the overall design time.

Another advantage is that since the estimation is based on the ratio of two wave powers, the absolute value of the wave amplitude is not required. This simplifies the problem of the source modeling.

### BRIEF DESCRIPTION OF THE DRAWINGS

FIG. 1 is a flowchart valid for all the embodiments of the present invention for designing a bypass device configuration of an electrical equipment.

FIG. 2 is a diagram for showing an embodiment of a design support system to support design of electrical equipment, according to the present invention.

FIG. 3 is a longitudinal section view of an example of a PCB with two planes for showing that simultaneous switching noise propagates as an electromagnetic wave between the power supply planes, that it is mostly reflected by the edges and that in part it is radiated.

FIG. 4A is a longitudinal section view of a PCB model for simulation with two planes assumed to be infinite, corresponding to FIG. 3.

FIG. 4B is a diagram for showing a local area very close to a noise source device (LSI) of the PCB model in FIG. 4A, according to the present invention.

FIG. 5 is a diagram for showing the local area where 1 bypass capacitor has been added close to the noise source via.

FIG. 6 is a top view of a rectangular PCB with two planes of the same dimensions, for explaining why the forward wave simplification works, according to the present invention.

FIG. 7 is a diagram for showing voltage observation points along a line surrounding the region of interest in the local area, according to the present invention.

FIG. 8 is a diagram for showing the local layout of a noise source LSI having five power vias and one capacitor, as in the example 1.

FIG. 9 is another diagram for showing the local layout of a noise source LSI having five power vias and four capacitors, as in the example 1.

FIG. 10 is a diagram for showing the expected far field ratio with forward waves of the example 1, according to the present invention.

FIG. 11 is a diagram for showing the far field ratio of the example 1 with commercial tool, using the whole PCB model according to related art.

FIG. 12A is a longitudinal section view of a second example of PCB with more than two planes to be designed.

FIG. 12B is a longitudinal section view of a first PCB model for simulation with planes assumed to be infinite, corresponding to FIG. 12A, according to the present invention.

FIG. 12C is a longitudinal section view of a second PCB model for simulation with planes assumed to be infinite, corresponding to FIG. 12A, according to the present invention.

FIG. 13 is a longitudinal section view of another PCB corresponding to the second example PCB, but having a pair of perfectly absorbing boundaries that create an electromagnetic field distribution similar to that of an infinite board.

FIG. 14 is a diagram for showing the horizontal mapping of the voltage between the bottom and top planes with 5 power vias and 31 ground vias, according to the example 2.

FIG. 15 is a diagram for showing the same mapping as FIG. 14 after that 5 ground vias, 5 power vias and 10 bypass capacitors have been added close to the sources.

FIG. 16 is a diagram for showing expected far field ratio with commercial tool and forward waves according to the example 2.

FIG. 17A is a schematic of a one-port noise source model with source impedance for one LSI power pin, according to the present invention.

FIG. 17B is a schematic of a multi-port noise source model with multi-port source impedance for several LSI power pins, according to the present invention.

FIG. 17C is a partial view of the PCB in FIG. 13 on large scale for showing multiple via ports.

### DESCRIPTION OF THE EMBODIMENTS

### The Outline of Composition

The present invention includes a computer readable medium that contains a computer program implementing the procedure that is described in this specification.

The term“a noise source device” in this invention is used to indicate an electronic device, such as a LSI, which comprises at least a noise source element.

The term “a noise source element” in this invention is used to indicate the equivalent circuit element connected to one via, such as a power via, a ground via, as a source of noise between planes.

The term “forward wave” in this invention is used to indicate the electromagnetic waves propagating among assumed infinite power supply planes from the noise source device (LSI) region outwards, that is without any reflections from the edges or other discontinuities outside the considered region.

In the present invention we propose to estimate the effect of current bypass devices very close to the noise source on the radiation by local simulations in the region around the noise source (noise source devices and noise source elements), based on their effect on the forward waves.

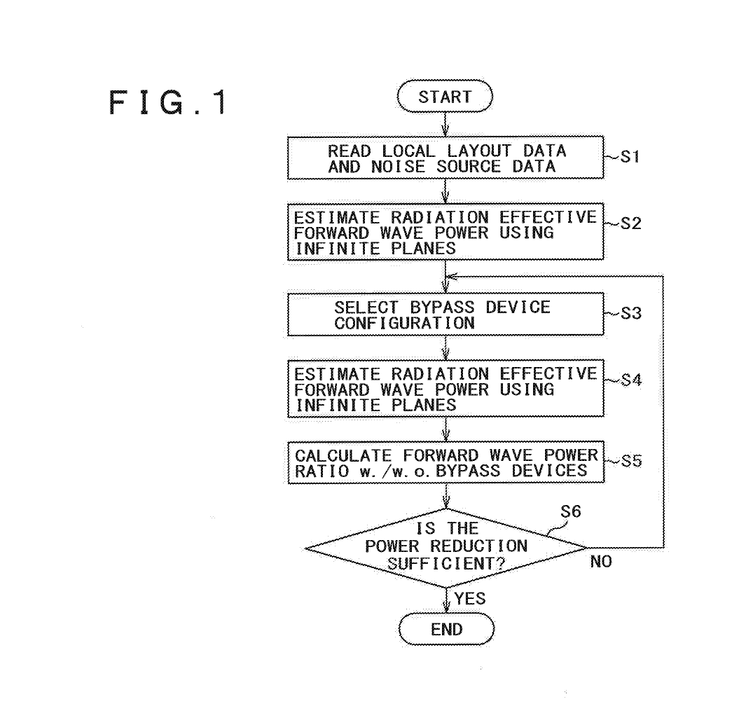

With reference to FIG. 1, the procedure starts with reading the local layout data and the noise source (a noise source device and noise source elements) data of the PCB to be designed, including components, and the information about (first step S1).

An electrical equipment model, such as a PCB model, for simulation is generated beforehand using a computer and it is stored in a database. The model has perfectly absorbing boundaries corresponding to assumed infinite power supply planes instead of board edge.

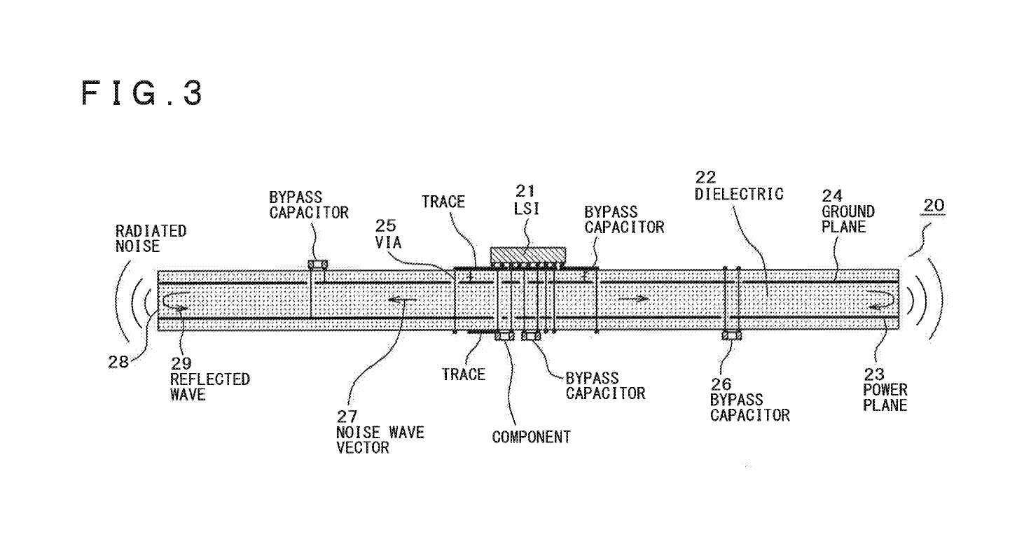

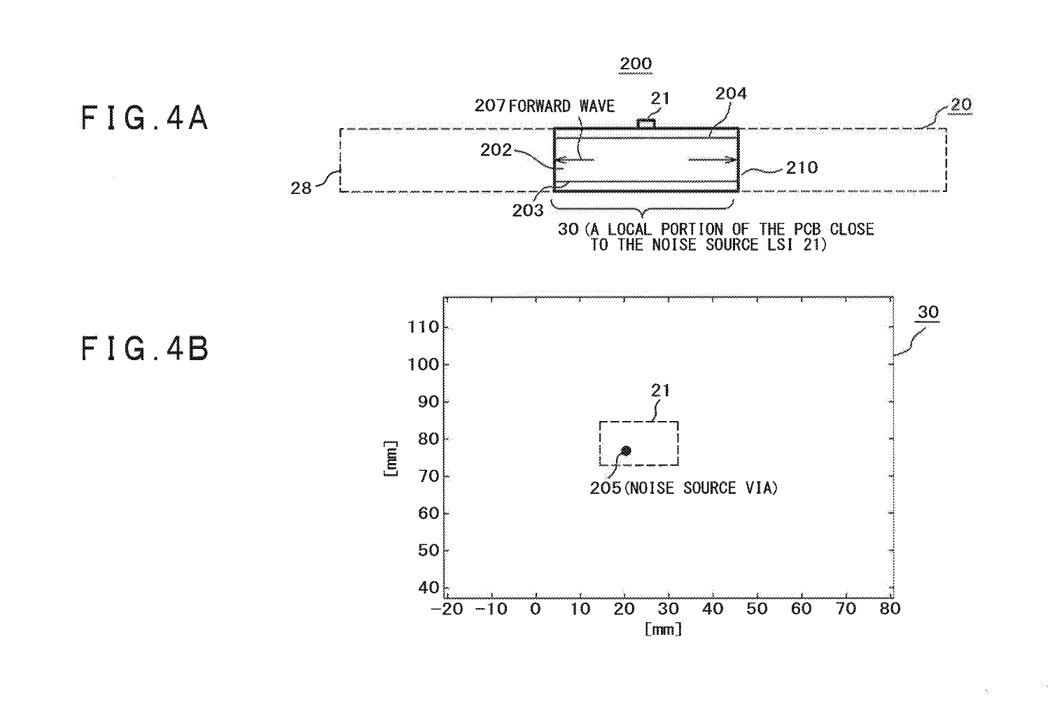

FIG. 4A is a longitudinal section view of a PCB model 200 for simulation with two planes (a ground plane 204 and a power plane 203 connected to a noise source) in dielectric 202 corresponding to the layout of the PCB 20 in FIG. 3, but having a pair of perfectly absorbing boundaries 210 instead of the board edges 28. That is, the PCB model 200 has a local area 30 with perfectly absorbing boundaries 210 assuming infinite planes which create an electromagnetic field distribution. The local layout data in the local area 30 include components, and the information about the noise source device (LSI) 21.

FIG. 4B is a diagram for showing a top view of the local area 30 of the model 200 having perfectly absorbing boundaries assuming infinite power supply planes instead of board edges 28, according to the present invention. In the noise source device (LSI) 21, there is a noise source element (connected to the noise source via 205). The local layout data to be read include the power and ground vias, and the components connected to power and ground planes (203, 204), in the local area of the model of the PCB, very close to the noise source LSI 21.

The radiation effective forward wave power 207 injected from the noise source (21, 205) into infinite power supply planes 210 of the model is estimated in the second step (S2). This forward wave power without capacitors (P_{w/o}) will be used as reference.

In order to approximately estimate the power of the radiation effective forward wave 207, the contour integral W of its squared voltage can be evaluated on a line surrounding the local noise source area. Dividing the squared voltage by the mode impedance to obtain the power density is not strictly required in this approximation, since later the power ratio will be used and not the absolute value.

The estimation of the effective forward wave power is made using the assumed infinite planes. Namely, all the estimation of radiation effective forward wave power 207 in the local area 30 of the model 200 are made using the perfectly absorbing boundaries 210 (the infinite planes) as shown in FIG. 4A, that is without considering the reflected waves 29 shown in FIG. 3.

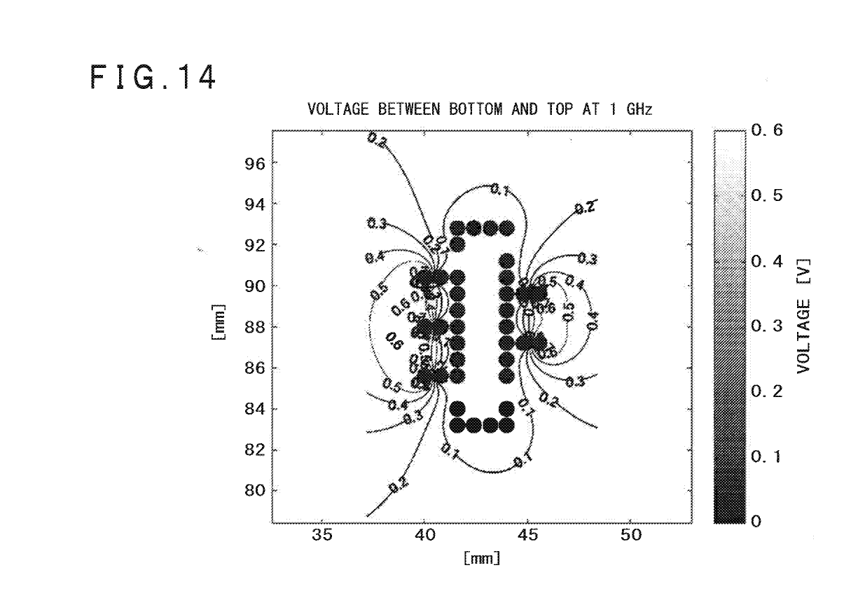

An optional two dimensional mapping of the radiation effective forward wave voltage among the top and bottom planes in this phase allows to visualize on a monitor device equipped with a graphical user interface (GUI), in which directions the noise is emitted, as shown for example in FIG. 14.

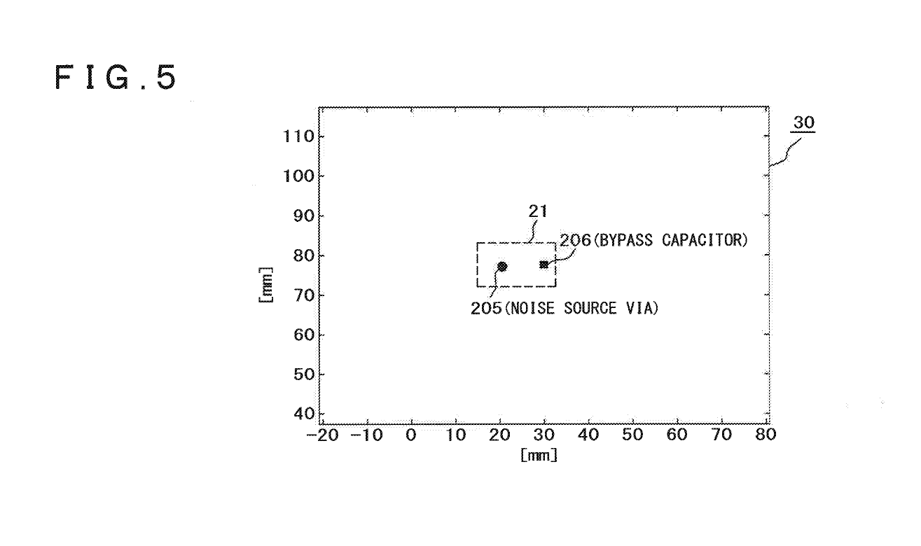

A configuration of current bypass devices is selected in the next third step (S3). In FIG. 5, there is a bypass capacitor 206 near the noise source element (via 205) in the local area 30.

The selection can be either automatic, if based on some optimization algorithms, or it is made by the user. Considering the spatial constraints usually present in a real PCB, a selection by the user is simpler to conduct in many cases, and a considerable reduction of estimated radiation can be obtained in a few repetition cycles. Particularly when the position of the current bypass devices must be selected by the user, the above two dimensional mapping is very useful. In general it is better to put the bypass devices as close as possible to the noise sources elements.

In the following step (S4), the equivalent radiation effective forward wave power 207 including the effect of the current bypass devices (P_{w}) is estimated, for example with the bypass capacitor 206.

Then, the ratio between this radiation effective forward wave power and the reference radiation effective forward wave power, (P_{w})/(P_{w/o}), is calculated in the next step (S5).

The advantage of the present approach is that only local simulations in the region around the noise source device (LSI) are required, reducing in this way the calculation time and the need for information about the layout and most of the components.

The decision whether the reduction is sufficient or not follows in the sixth step (S6). If the reduction is sufficient the procedure is completed, otherwise a new configuration of current bypass devices must be selected (S3), either by the user or automatically. In many cases, however, it is more convenient that the user himself decides at each cycle whether the reduction is sufficient or not based on several factors that include the cost of adding current bypass devices and the trend of reduction due to previous selections of current bypass devices.

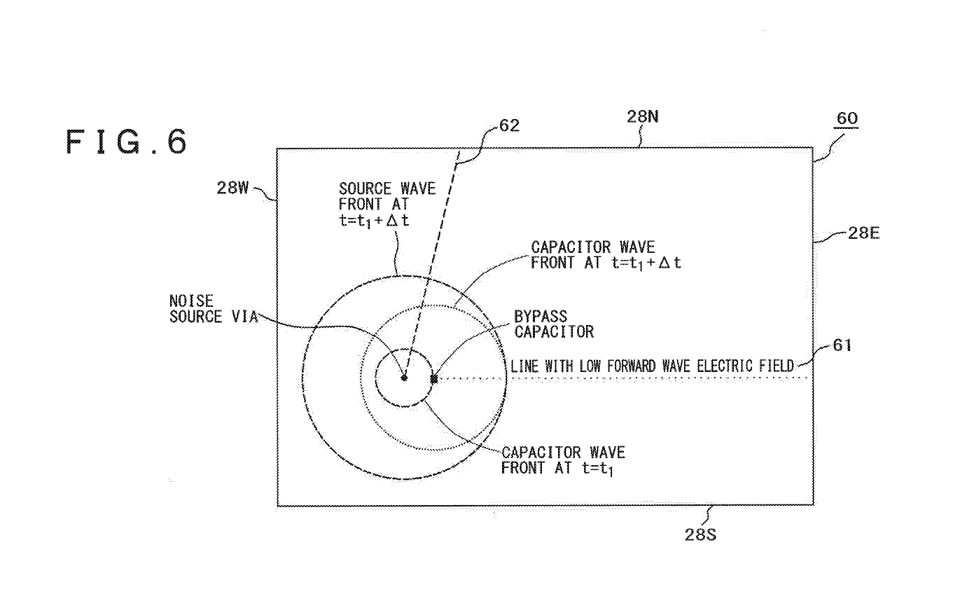

An attempt to explain why the forward wave simplification works is shown in FIG. 6. The figure represents the top view of a rectangular PCB 60 with two planes (one power plane and one ground plane) of the same dimensions. In the PCB 60, one noise source element (via) and one current bypass device (in this example a bypass capacitor) are present. The noise source element generates a cylindrical electromagnetic wave between the planes that reaches the current bypass device at the time t₁. Assuming that the current bypass device has very low impedance, it generates a second cylindrical wave that has approximately the opposite voltage (180 degrees of phase difference) with respect to the incident wave. The two front waves at the time t₂=t₁+αt are shown in the FIG. 6, before reaching the edges (28N, 28E, 28S, and 28W) of the PCB 60. Along the direction indicated by the dot line 61 in the figure, where the incident and induced waves have the same direction of propagation and speed component, the voltage is small. In other directions, such as the direction indicated by the dot line 62, however, there is a difference of phase that is dependent on the separation between the noise source element and the current bypass device, and on the wavelength.

This means that in general the voltage is not zero and particularly at high frequencies the induced wave can even enhance the incident one at some frequencies and in some directions. Each time the waves reach the edges (28N, 28E, 28S, and 28W) of the PCB 60, radiation occurs, but most of the waves are reflected back (see FIG. 3) creating resonances that affect the overall voltage distribution, including the voltage along the edges and therefore the radiation.

Adding additional current bypass devices changes the resonance distribution in a complex way, particularly at high frequencies, generally reducing the radiation at some frequencies but increasing it at other frequencies. The balance depends on how well the bypass devices and their position have been chosen, but also on the amplitude of the parallel plane resonances, which is related to the quality factor.

Under certain circumstances, the effect of the current bypass devices is dominant over the effect of the board resonances, and therefore if the forward noise wave is reduced, the overall noise is expected to be reduced as well. This is the case for example for frequencies well above the first parallel plane resonance, where the quality factor of the plane resonances is relatively small. Frequencies below the first parallel plane resonance could represent other favorable circumstances, but they are still to be confirmed.

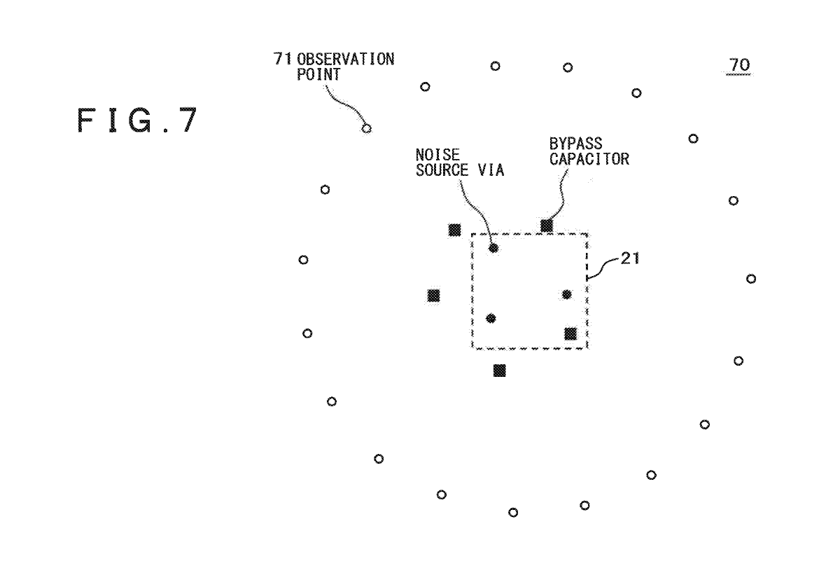

In order to evaluate the power of the radiation effective forward wave, the voltage is evaluated in many points along a line surrounding the region of interest (around the noise source device 21) in the local area 70, as shown for example in FIG. 7, where the line is circular. The observation points 71 for the voltage do not need to be in a circle, and their number and distance from the noise sources element is not fixed by any algorithm, however, they must be selected in such a way that they can approximately catch the angular variation of the voltage. From the voltage and current in the observation points 71, the total radiation effective forward wave power can be estimated. A good approximation of the power ration can be obtained also by using only the voltage.

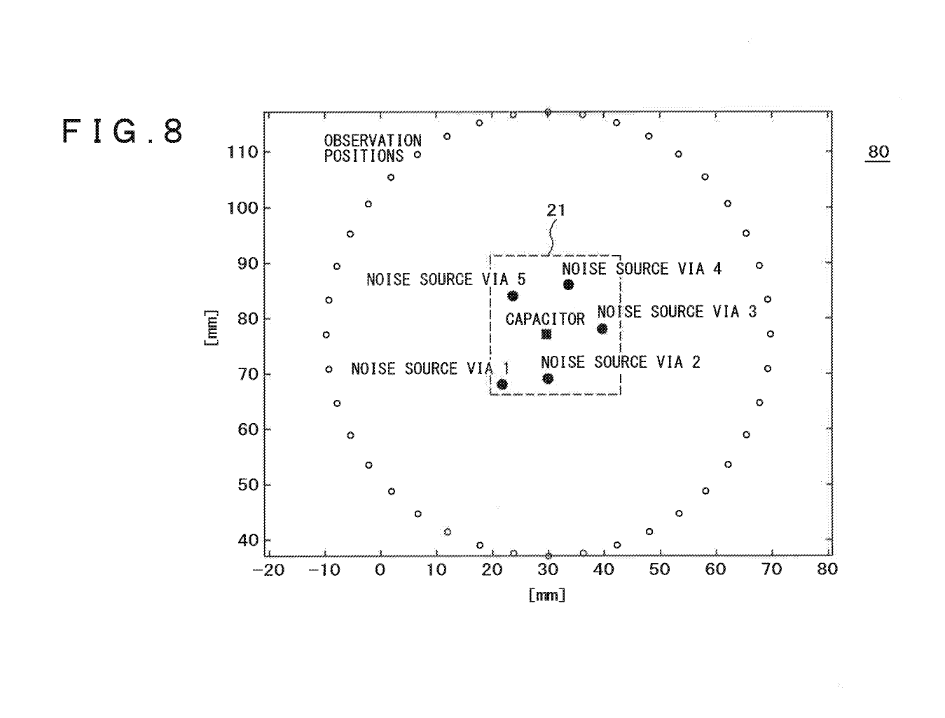

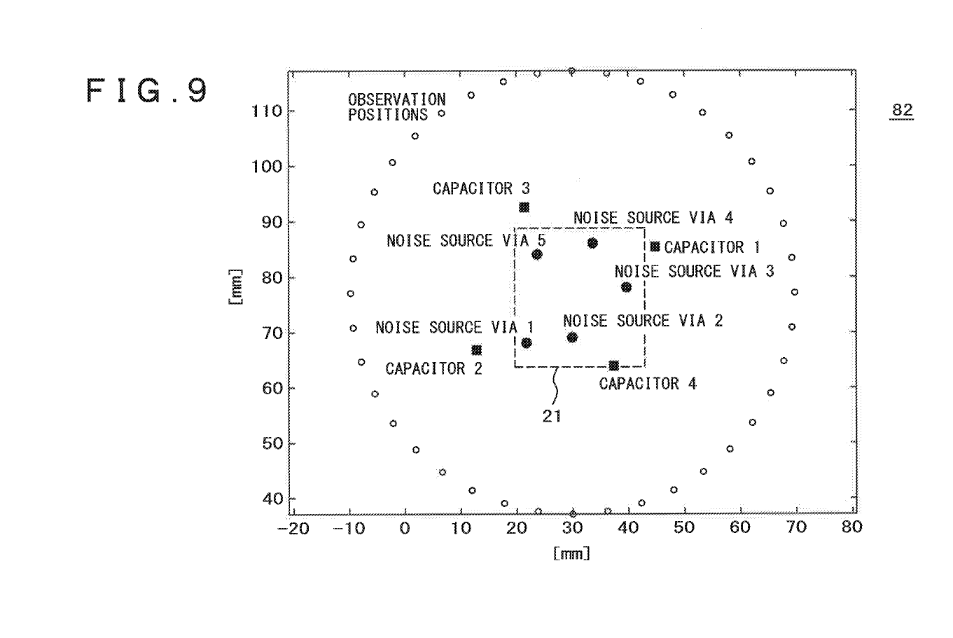

In order to make more clear these concepts, one simple example is presented in the FIGS. 8, 9, 10 and 11. The example 1 comprises one PCB having two full planes (one power and one ground plane) of approximately 250 mm size. The noise source device (LSI) has five power vias connected to the noise sources elements, and different combination of bypass capacitors are tested, in particular 1, 2, or 4 bypass capacitors as shown in FIGS. 8 and 9. According to FIG. 8, there are five noise source vias 1-5 and one bypass capacitor in the region of interest (21) in the PCB 80. According to FIG. 9, there are five noise sources vias 1-5 and four bypass capacitors in the region of interest (21) in the PCB 82.

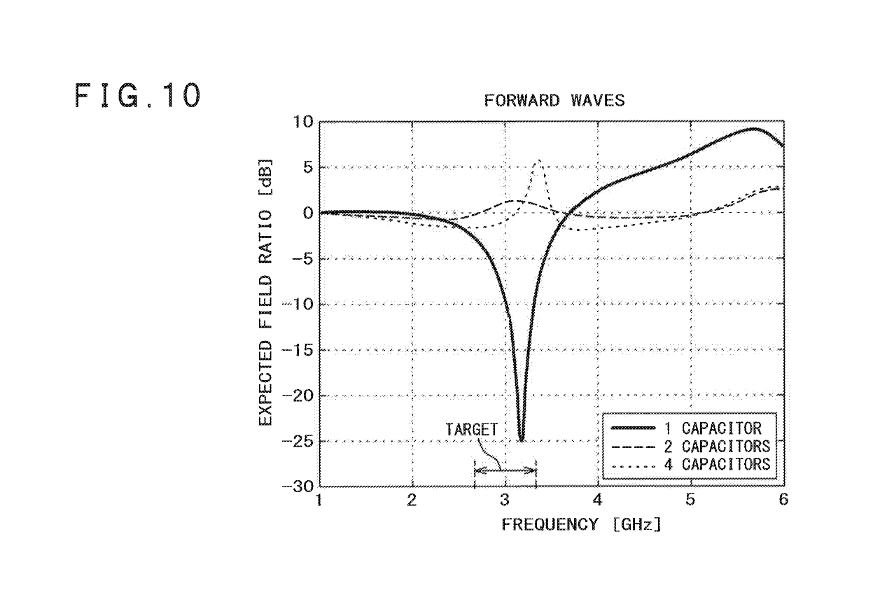

When only the forward waves are used according to the present invention, the expected far field ratio with any of the capacitor configuration (1, 2, or 4 as shown in FIGS. 8 and 9) becomes that of FIG. 10. In this case, by utilizing 1 capacitor, the reduction of the expected far field ratio is sufficient within a required target frequency band, thus, the procedure may be completed.

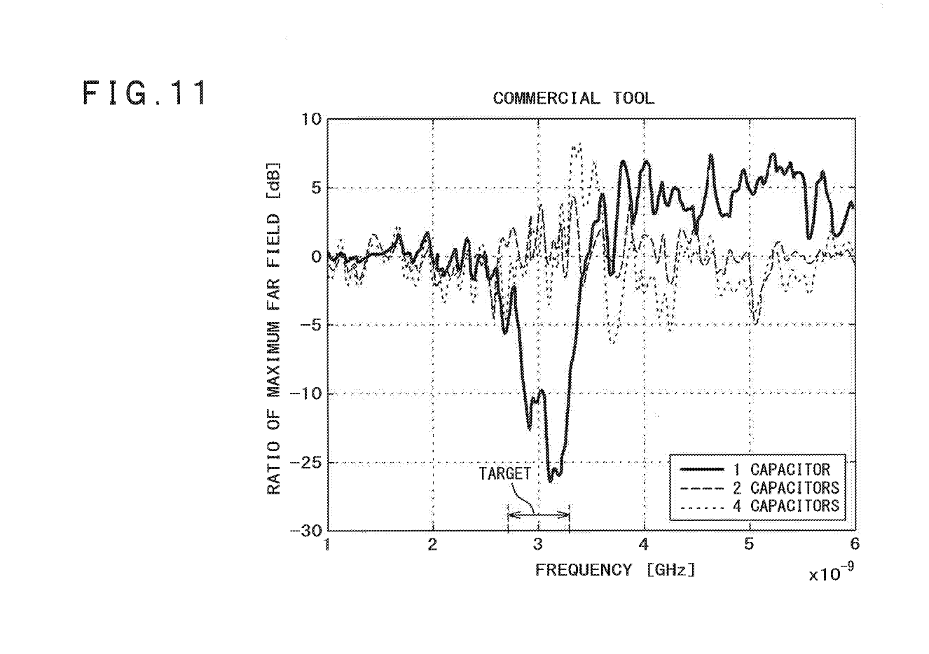

On the other hand, when the radiation at three meter distance is estimated with a commercial tool using the whole PCB model, the ratio of the maximum field with any of the capacitor configuration (1, 2, or 4 as shown in FIGS. 8 and 9) and the maximum field without any capacitor is shown in FIG. 11.

By comparing FIGS. 10 and 11, it can be observed that all the oscillations due to the board resonances are not present when the forward waves are used, but the dominant effect of the bypass capacitors is well represented.

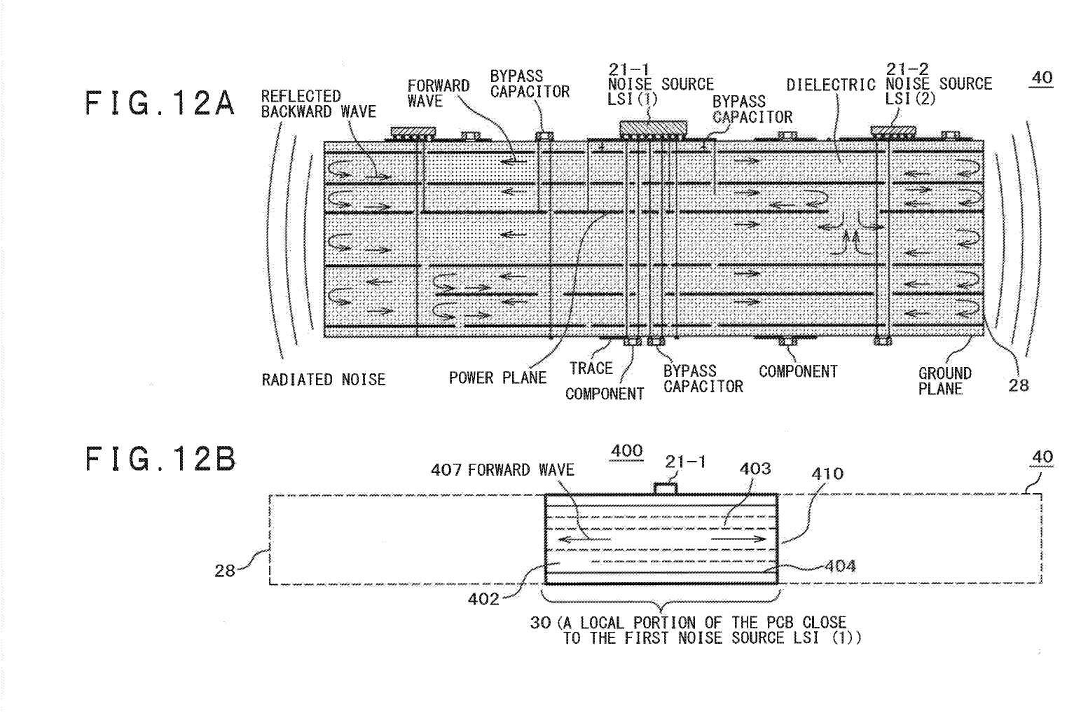

Next, as a second example, it is explained another case that a PCB more than two planes, as shown in FIG. 12A, is designed. FIG. 12A is a longitudinal section view of an example of multilayer PCB 40 to be designed. In the PCB 40, two noise source devices, the first noise source LSI 21-1 and the second noise source LSI 21-2, are provided.

FIG. 12B is a longitudinal section view of one model 400 for simulation corresponding to the first noise source LSI 21-1 of multilayer PCB 40 in FIG. 12A. As shown in FIG. 12B, the model 400 includes power planes and ground planes (403, 404) in dielectric 402, and perfectly absorbing boundaries 410 that create an electromagnetic field distribution assuming an infinite board. Only local simulations, estimating radiation effective forward wave power 407, are required in the region of the local area 30 around the noise source LSI 21-1 of the multilayer PCB 40.

FIG. 12C is a longitudinal section view of another model 420 for simulation corresponding to the second noise source LSI 21-2 of multilayer PCB 40 in FIG. 12A.

For each of models 400 and 420, estimation of the effect of current bypass devices to the noise source device is performed separately.

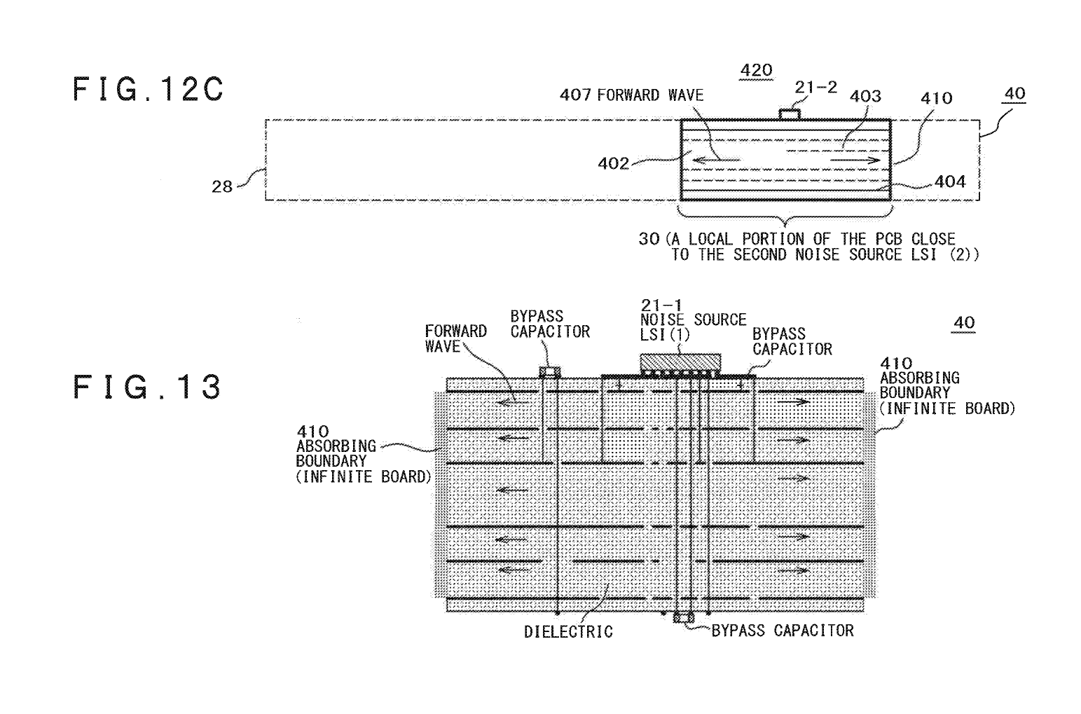

FIG. 13 is a longitudinal section view of PCB corresponding to that of FIG. 12A, but having perfectly absorbing boundaries 410 that create an electromagnetic field distribution similar to that of an infinite board. Required simulation area of the first noise source LSI 21-1 in FIG. 12A is reduced to that of FIG. 13, according to the present invention.

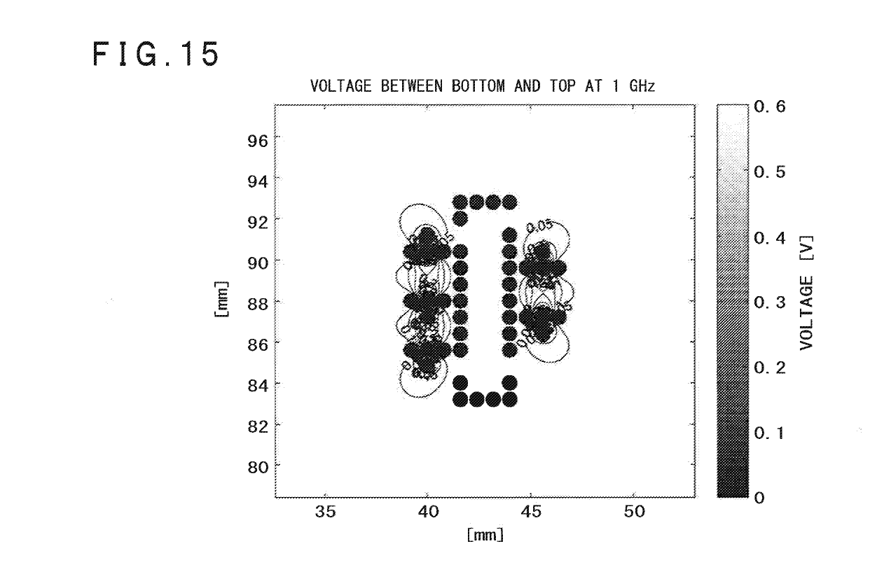

Regarding the second example, a more realistic example is shown in the FIGS. 14-15.

In this case, a complex stack-up with 7 ground planes and 1 power plane on the fourth layer is considered. The reference layout has 31 ground vias and 5 power vias below the noise source LSI. FIG. 14 shows the mapping of the forward wave voltage between the bottom and top ground plane, plotted on a monitor of an output unit, which is important for a user for estimating the directions with large noise emissions (radiation effective forward wave).

FIG. 15 shows the same mapping after that 5 ground vias and 10 bypass capacitors have been added close to the noise sources LSI in the local area.

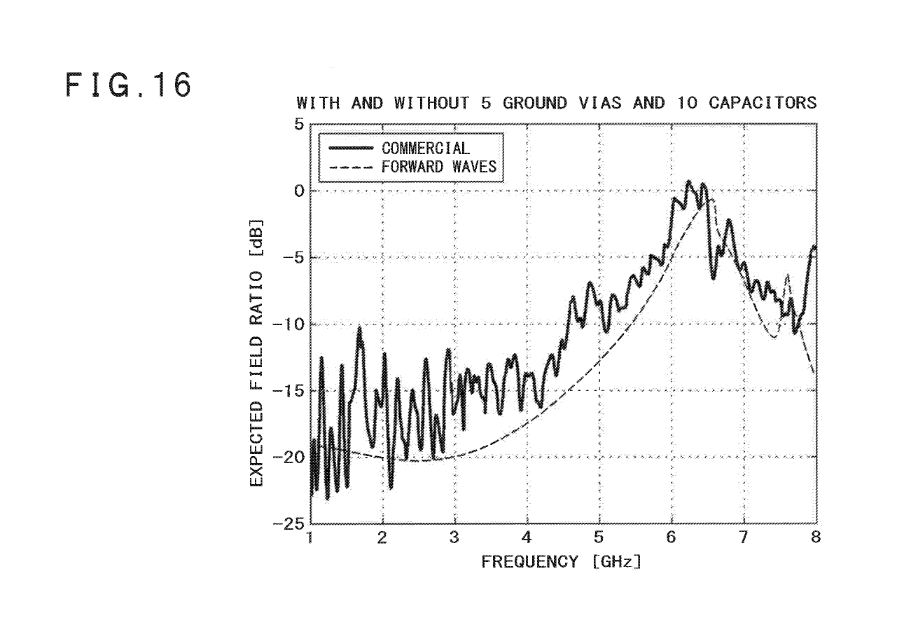

In FIG. 16, the ratio of the estimated far field by means of the radiation effective forward wave power is plotted. The emission reduction is very clearly visible and it is quantitatively evaluated in terms of the estimated field ratio in FIG. 16. In the same figure, the results obtained with a commercial software that analyzes the whole board are also plotted, and the similarity is remarkable.

The present invention is applicable not only to a PCB but also to electrical equipment comprising a PCB. Similarly to the above PCB model, for other electrical equipment as well it is required to generate a PCB simulation model beforehand using a computer, and it to store the model in a database. In this case as well, the simulation model is limited to local areas around noise sources and perfectly absorbing boundaries assuming infinite power supply planes are used instead of PCB edges.

### Embodiment 1

The main embodiment is described in FIG. 1, whereas the selection of the position of the current bypass devices and the decision whether the power reduction is sufficient or not, are made by the user.

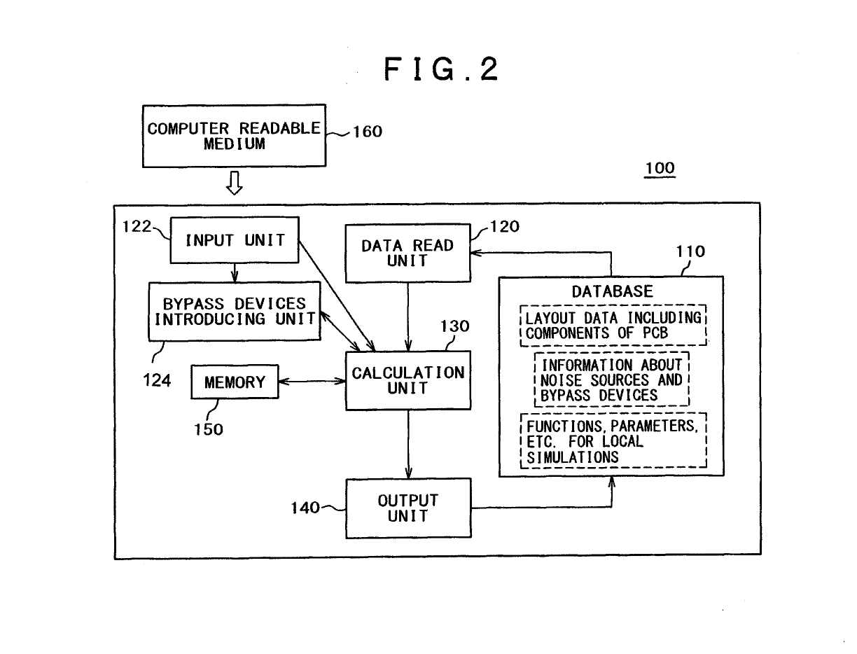

FIG. 2 is a diagram for showing an embodiment of a design support system 100 to support design of electrical equipment, according to the present invention. For the system 100, a computer may be used to implement the method described in FIG. 1.

The system 100 comprises;

a database 110 for storing layout data, noise source (a noise source device and noise source elements) data of the simulation model of a printed circuit board having assumed infinite power supply planes, and calculation results;

an input unit 120 for imputing data to the database 110, for example, layout data including components of the PCB model, information about noise sources, bypass devices, and necessary data for local simulations, such as functions, parameters, etc.;

a calculation unit 130 for estimating the radiation effective forward wave power injected into assumed infinite power supply planes of the model from the noise source without and with current bypass devices, and for calculating their ratio; and

an output unit 140 to plot and save calculation results.

The computer system for the system 100 includes a processor and a memory 150 as the calculation unit 130 coupled to the database 110, the input unit 120, and the output unit 140. A computer readable medium 160 stores a computer program including a set of code to be executed. The processor is configured to executing instructions received from the computer readable medium 160 or from the input unit for designing a printed circuit board. For executing instructions, necessary data are read out from the database 110. The computer readable medium 160 may include various types of memory. Results obtained by performing the method using the processor are forwarded to output unit 140. The Output device may be a monitor, a printer, or any other output devices. One monitor device equipped with a graphical user interface (GUI) may be used for the input unit and the output unit.

In FIG. 1, the local layout of the model to be read in the first step (S1) of the procedure comprises the plane stack-up, the power and ground via layout very close to the noise source device (LSI), and the components connected to power and ground planes very close to the noise source device, which typically are bypass (or decoupling) capacitors.

Regarding the dimensions of the area of interest (around the noise source LSI or noise source elements), no clear rule exists at present, but in many cases involving BGA packages it is not required to use an area larger than the package itself. The required region is expected to be smaller at higher frequencies. A heuristic way to estimate its size is that of starting with a very small one at first, and increasing its size by looking at the effect on the estimated radiation.

In the present invention, we propose to estimate the effect of current bypass devices in a local area 30 of the model very close to the noise source LSI on the radiation, based on their effect on the forward waves. The advantage of the present approach is that only local simulations in the region around the noise source LSI are required, reducing in this way the calculation time and the need for information about the layout and most of the components.

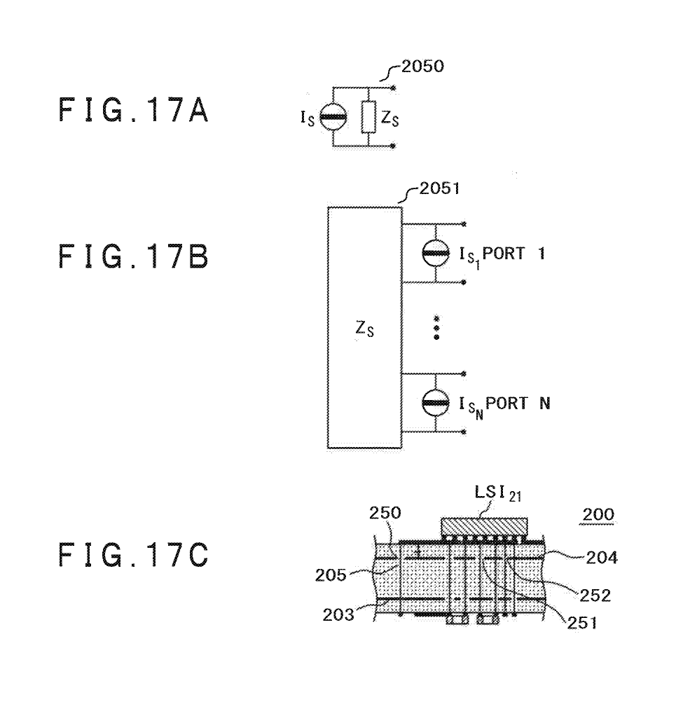

The relevant source data comprises basically the noise source model 2050 of FIG. 17A for one-port noise source elements and the noise source model 2051 of FIG. 17B for multi-port noise source elements. These noise source models 2050, 2051 are connected to the power vias on the LSI side when the first plane close to LSI is a ground plane, as it is usual in PCB design. Shall the first plane below the LSI be a power plane, the noise source models must be connected to the ground vias.

For example, in FIG. 17C, on the ground plane 204 of the PCB 200, there are three via ports 250, 251 and 252 around the noise source LSI 21. For those three via ports, three noise source models 2050 or one noise source model 2051 can be used.

Assuming a linear behavior of the noise source, the most general case consists in frequency dependent complex current sources with multi-port impedances. In practice such complex models are often not available and the design can be conducted using simplified models. The simplest model of the present invention consists in one unitary real current source without any impedance (that is infinite impedance or zero admittance matrices) for each power via.

The calculation of the radiation effective forward wave power P in the second step (S2) in FIG. 1 can be more simply presented in the case of two planes with only a vector of ideal noise source current Iₛ without source impedance matrix, and with observation points assumed to be continuously distributed along a circle of radius p. In this case the voltage in one observation point of cylindrical coordinates (ρ,φ) can be written as V(ρ,φ)=Z_{φs} Iₛ, where Z_{φs} is a matrix of the same dimensions as the transposed vector of the current, Iₛ^{T}, and represents the transfer impedance between the source current and the observation voltage for infinite planes. It is well known to a person skilled in the art that this can be conveniently expressed in terms of cylindrical harmonics, with the simplest approximation obtained using the lowest order in the cylindrical expansion.

Using cylindrical harmonics it is also possible to express the current density in the observation position J(ρ,φ).

From the current density and the voltage, the complex power density propagating in the direction orthogonal to the circle can be calculated, and by integrating along the circumference the real part of the power density, the total forward wave power P can be obtained.

However, for the purpose of estimating the far field ratio using the radiation effective forward wave powers in the step (S5), the total forward wave power P can be approximated by the integral of the squared voltage W along the circumference. Thus, in many cases it is sufficient to calculate the integral of the squared voltage Walong the circumference, as in the following equation (1).

### [Math.1]

$$W = {\int }_{0}^{2 π} {\vert {\overline{Z}}_{φ s} {\overline{I}}_{s} \vert}^{2} ρ d φ \qquad ( 1 )$$

A good approximation of the ratio (P_{w})/(P_{w/o}) can be obtained by integrating directly the squared voltage with capacitors (W_{w}) and the squared voltage without capacitors (W_{w/o})

The general case with source impedance and more than two planes of the PCB, is similar in principle.

The key issue consists in estimating the power of the radiation effective forward wave voltage, that is the total forward wave voltage between the bottom plane and the top plane in the observation positions, V^{T}(ρ,φ), because the far field radiation from the edges depends on the total edge voltage. This can be simply obtained as the summation of the forward wave voltages Vⁱ(ρ,φ) among the planes: V^{T}(ρ,φ)=ΣVⁱ(ρ,φ). The calculation of the inter-plane voltage Vⁱ(ρ,φ) in the observation position can be made with cylindrical harmonics similarly as above, as long as the current in all the via ports is known. One possible method to calculate the via port current makes use of the analysis technique for multilayer PCBs described in the Non Patent Document 3, including a definition of the via ports for multilayer PCBs. In short, first the PCB admittance matrix is calculated according to the Non Patent Document 3, next the port voltages and currents at the LSI-PCB interface are calculated, then with a sort of back-substitution the PCB internal via port currents are calculated, and finally from the port via current the inter-plane voltage Vⁱ(ρ,φ) in the observation positions and the radiation effective forward wave voltage V^{T}(ρ,φ) can be calculated.

The next step (S3) in the procedure described in FIG. 1 is the selection of a configuration of current bypass devices.

In this embodiment this selection is made by the user also with the help of a two-dimensional mapping of the radiation effective forward wave voltage distribution between the bottom and top planes, V^{T}(ρ,φ).

The radiation effective forward wave power P with the new current bypass device configuration is estimated in the next step (S4). In the simple example above, with a two plane board having only ideal noise sources current Iₛ, assuming that bypass capacitors are added between the power and ground planes, their effect on the radiation can be estimated based on the forward waves in the following way. The source port voltage Vₛ, the capacitor port voltage V_{c}, and the observation point voltage V(ρ,φ) can be calculated from the source and capacitor port currents, Iₛ, and I_{c}, respectively, by means of an impedance matrix having elements that can be expressed with cylindrical harmonics as in the following equation (2).

### [Math.2]

$$[ \begin{matrix}{\overline{V}}_{s} \\ {\overline{V}}_{c} \\ V ( ρ , φ )\end{matrix} ] = [ \begin{matrix}{\overline{\overline{Z}}}_{ss} & {\overline{\overline{Z}}}_{sc} \\ {\overline{\overline{Z}}}_{cs} & {\overline{\overline{Z}}}_{cc} \\ {\overline{Z}}_{φ s} & {\overline{Z}}_{φ c}\end{matrix} ] [ \begin{matrix}{\overline{I}}_{s} \\ {\overline{I}}_{c}\end{matrix} ] . \qquad ( 2 )$$

The PCB port voltage V_{c} and current I_{c} at the capacitor locations are related by a generalized capacitor impedance matrix Z_{c} that includes the microstrip parasitics, V_{c}=−Z_{c} I_{c}, where the minus sign is due to the direction of the port current. Therefore, the voltage in the observation positions can be obtained with the following equation (3).

[Math.3]

V(ρ,φ)=[Z̅_{φs}−Z̅_{φc}(Z̅_{cc}+Z̅_{c})⁻¹Z̅_{cs}]Īₛ. (3)

Similarly as before, in order to calculate the ratio of the total power with capacitors and without capacitors in the step (S5), since the estimation is based on the ratio of two wave powers (P_{w}) and (P_{w/o}), the absolute value of the wave power P is not required. Furthermore, the forward wave power P can be approximated with the integral of the squared voltage W along the circumference. In many cases, a good approximation of the ratio of the expected far field with capacitors (E_{w}), and far field without capacitors (E_{w/o}) can be obtained by integrating directly the squared voltage with capacitors (W_{w}), and the squared voltage without capacitors (W_{w/o}), as in the following equation (4).

### [Math.4]

$$\frac{{‖ {E}_{w} ‖}^{2}}{{‖ {E}_{w / o} ‖}^{2}} \approx \frac{{P}_{w}}{{P}_{w / o}} \approx \frac{{W}_{w}}{{W}_{w / o}} = \frac{{\int }_{0}^{2 π} {\vert [ {\overline{Z}}_{φ s} - {{\overline{Z}}_{φ c} ( {\overline{\overline{Z}}}_{cc} + {\overline{\overline{Z}}}_{c} )}^{- 1} {\overline{\overline{Z}}}_{cs} ] {\overline{I}}_{s} \vert}^{2} d φ}{{\int }_{0}^{2 π} {\vert {\overline{Z}}_{φ s} {\overline{I}}_{s} \vert}^{2} d φ} \qquad ( 4 )$$

The procedure for the general case with source impedances and more than two planes is exactly the same as the one described above for the second step (S2) when more than two planes are present. The only difference is the change in the layout caused by the additional current bypass devices. The ratio of the radiation effective forward wave power (P) without and with current bypass devices can be approximately calculated again using the ratio of the integral (W) of the squared forward wave voltage (|V_{T}|²) along a closed line (C) surrounding the noise source, which can be calculated as in the following equations (5) and (6).

$$\begin{matrix}[ Math . 5 ] & \\ W = {∮}_{C} {\vert {V}_{T} \vert}^{2} d l & ( 5 ) \\ [ Math . 6 ] & \\ \frac{{‖ {E}_{w} ‖}^{2}}{{‖ {E}_{w / o} ‖}^{2}} \approx \frac{{P}_{w}}{{P}_{w / o}} \approx \frac{{W}_{w}}{{W}_{w / o}} & ( 6 )\end{matrix}$$

The next step (S6) in the procedure described in FIG. 1 is the decision whether the reduction is sufficient or not. In this main embodiment this decision is made by the user, who can either accept the present configuration or select a new configuration of current bypass devices.

### Second Embodiment

According to a second embodiment, in the second and fourth steps (S2 and S4) in FIG. 1, the radiation effective forward wave voltage in the observation location is calculated with methods different from that described in the Non Patent Document 3. Alternative techniques can use for example a different via model, or a different algorithm for connecting in cascade the single plane pairs, such as ABCD-matrices or transmission (T-) matrices instead of the Y-matrix. Completely different numerical techniques can be also used, for example the method of moments (MoM), or even the finite element method (FEM), the finite difference method (FDM) in time or frequency domain, the finite integration method (FIM), as long as absorbing boundary conditions are used for the external boundaries, simulating in this way the conditions of infinite planes.

### Third Embodiment

According to a third embodiment, in the sixth step (S6) in FIG. 1, the decision whether the reduction is sufficient or not, and the selection of the new configuration of current bypass devices in the third step (S3) are made automatically with an optimization procedure. For example genetic algorithms can be used for selecting the new configuration. The decision can be made based on a target reduction that the user can select before starting the optimization. Alternatively, the optimization can aim to reach the minimum radiation effective forward wave power within a constrained space selected by the user before starting the optimization. The radiation effective forward wave power can be estimated with the methods described in the first and second embodiments.

1. A design support system for designing an electrical equipment, comprising:
a database for storing layout data, noise source data of a model of the electrical equipment, and calculation results; wherein the model includes assumed infinite power supply planes;
a data reading unit for reading noise source data and local layout data of a local area around a noise source of the model, from the database;
a bypass devices introducing unit for introducing current bypass devices to the local area; and
a calculation unit for estimating the power of the radiation effective forward wave, which corresponds to the equivalent wave obtained by algebraically adding up voltages and currents of the single waves propagating among assumed infinite power supply planes, injected into the infinite power supply planes of the model from the noise source without current bypass devices and with current bypass devices, and for estimating their power ratio.

2. The design support system according to claim 1,
wherein the calculation unit uses cylindrical harmonics to estimate the radiation effective forward wave power injected into the infinite power supply planes.

3. The system described in claim 1,
wherein, in order to evaluate the power of the radiation effective forward wave, the radiation effective forward wave voltage is evaluated in plural points surrounding the region of the noise source.

4. The design support system according to claim 3,
wherein, the radiation effective forward wave power (P) is approximately calculated using the integral (W) of the squared forward wave voltage (|V_{T}|²) along a closed line (C) surrounding the noise source, as in the following equation (5).
[Math.5]
W=φ_{C}|V_{T}|²dl (5)

5. The design support system according to claim 3,
wherein, in order to calculate the ratio of the expected far field with current bypass devices (E_{w}), and far field without current bypass devices (E_{w/o}), an approximation of the ratio of the radiation effective forward wave power with current bypass devices (P_{w}) and without current bypass devices (P_{w/o}) can be obtained by integrating along a closed line (C) surrounding the noise source the squared radiation effective forward wave voltage with capacitors (W_{w}), and the squared radiation effective forward wave voltage without capacitors (W_{w/o}), as in the following equation (6).
[Math.6]
$$\frac{{‖ {E}_{w} ‖}^{2}}{{‖ {E}_{w / o} ‖}^{2}} \approx \frac{{P}_{w}}{{P}_{w / o}} \approx \frac{{W}_{w}}{{W}_{w / o}} \qquad ( 6 )$$

6. The system according to claim 1,
wherein the bypass device introducing unit introduces a configuration of the current bypass devices automatically.

7. The design support system according to claim 1,
wherein the electrical equipment is a printed circuit board,
wherein the noise source includes a LSI as a noise source device, and
wherein, when the printed circuit board to be designed has plural noise source devices, the model is prepared for each of the noise source devices.

8. The system according to claim 1, further comprising
a monitor device equipped with a graphical user interface,
on the monitor device, the bypass devices introducing unit plots the horizontal distribution at one frequency of the radiation effective forward wave voltage between the bottom and top planes, for accepting the selection of the positions and values of current bypass devices by a user.

9. The system according to claim 8,
wherein the calculation unit uses cylindrical harmonics to estimate the radiation effective forward wave power injected into the infinite power supply planes.

10. A design support method for designing an electrical equipment, executed by a computer, comprising procedures of:
creating a model of the electrical equipment, wherein the model includes assumed infinite power supply planes;
reading local layout data and noise source data of the model;
estimating the power of the radiation effective forward wave, which corresponds to the equivalent wave obtained by algebraically adding up voltages and currents of the single waves propagating among assumed infinite power supply planes, injected into the infinite power supply planes from the noise source;
estimating the radiation effective forward wave power injected into infinite power supply planes from the noise source after the introduction of current bypass devices; and
calculating the ratio of the above radiation effective forward powers, to estimate the effect of the current bypass devices on the radiated field.

11. The method according to claim 10,
wherein, for the estimation of the radiation effective forward wave power, cylindrical harmonics are used.

12. The method according to claim 10,
further comprising steps of:
selecting configuration of current bypass devices automatically, and
deciding whether the above ratio is sufficient or not, automatically.

13. The method according to claim 10,
wherein the electrical equipment is a printed circuit board, and
wherein, in order to simplify the selection of the current bypass device position, the horizontal distribution at one frequency of the radiation effective forward wave voltage between the bottom and top planes is plotted on a display.

14. A computer readable medium with a computer program including a set of code, the program causing the following operations to a computer:
creating a model of the electrical equipment, wherein the model includes assumed infinite power supply planes;
reading local layout data and noise source data of the model;
estimating the power of the radiation effective forward wave, which corresponds to the equivalent wave obtained by algebraically adding up voltages and currents of the single waves propagating among assumed infinite power supply planes, injected into the infinite power supply planes from the noise source;
estimating the radiation effective forward wave power injected into the infinite power supply planes from the noise source after the introduction of current bypass devices; and
calculating the ratio of the above powers to estimate the effect of the current bypass devices on the radiated field.
